(19) United States
(12) Patent Application Publication
(10) Pub. No.: US 2008/0081433 A1
(43) Pub. Date: Apr. 3, 2008

(54) Method for Forming a Shallow Trench Isolation Structure

(75) Inventors: Leong Tce Koh, Shanghai (CN); Zhengying Wei, Shanghai (CN); Saiya Zhu, Shanghai (CN); Jian Weng, Shanghai (CN)

Correspondence Address: SQUIRE, SANDERS & DEMPSEY L.L.P., 1 MARITIME PLAZA, SUITE 300, SAN FRANCISCO, CA, 94111, US

(73) Assignee: SEMICONDUCTOR MANUFACTURING INTERNATIONAL (Shanghai) CORPORATION, Shanghai (CN)

(21) Appl. No.: 11/856,683

(22) Filed: Sep. 17, 2007

(30) Foreign Application Priority Data
Sep. 30, 2006 (CN) 200610116858.X

(51) Int. Cl. H01L 21/31; H01L 21/76

(52) U.S. Cl. 438/424; 438/778; 257/E21.54; 257/E21.24

(57) ABSTRACT

A method for forming a shallow trench isolation structure, comprising the steps of: sequentially forming a pad oxide layer and an etch barrier layer on a semiconductor substrate, and sequentially defining the etch barrier layer, the pad oxide layer, and the substrate to form a trench; forming a liner oxide layer on the inner surface of the trench; forming a isolation oxide layer which fills up the trench and covers the sidewall of the pad oxide layer and the etch barrier layer; planarizing the isolation oxide layer until the etch barrier layer has been exposed; sequentially removing the etch barrier layer and the pad oxide layer on the substrate; forming a spin-on-glass layer on the substrate and the isolation oxide layer such that the recess on the sidewall of the trench is filled with the spin-on-glass; performing the process of removing the spin-on-glass layer until both of the substrate and the isolation oxide layer have been exposed. The disadvantage that the recess is formed on the sidewall of the trench can thus be overcome.

### FIELD OF THE INVENTION

The present invention relates to the field of semiconductor fabrication process technology, and more particularly, to a method for forming a shallow trench isolation structure.

### BACKGROUND OF THE INVENTION

Semiconductor integrated circuits generally comprise active regions and isolation regions therebetween. The isolation regions are formed before the fabrication of active devices. In the prior art, the methods for forming isolation regions generally include Local Oxidation of Silicon (LOCOS) Isolation and Shallow Trench Isolation (STI), etc. During the LOCOS isolation process, a silicon nitride layer is deposited on the surface of the wafer, and then the silicon nitride layer is etched. Silicon oxide is grown by the oxidation of a portion of recessed regions. Active devices are formed in the area defined by the silicon nitride layer. However, due to the difference of the thermal expansion performance between the silicon nitride layer and the silicon substrate during the oxidation, bird's beaks are formed at the edge of the silicon nitride layer, as shown in FIG. 1. Such bird's beaks occupy physical space, thus increasing the circuit volume. Moreover, the wafer may be broken by the stress during the oxidation. Therefore, The LOCOS isolation is only applicable for the design and fabrication of large-sized devices.

As the semiconductor industry enters the deep submicron age, sub-0.18 μm devices, e.g. the isolation layers between the active regions of MOS circuits are usually formed by the STI process. The STI process is an effective method for resolving the problem of “bird's beaks” due to the LOCOS isolation process for MOS circuits.

FIGS. 2a to 2f are cross-sectional views of a conventional shallow trench isolation structure. First, as shown in FIG. 2a, a pad oxide layer 110 and an etch barrier layer 120 are formed on a semiconductor substrate 100. A patterned photoresist is formed on the etch barrier layer 120. The pad oxide layer 110 and the etch barrier layer 120 are etched using the patterned photoresist as a mask to expose the substrate 100. As shown in FIG. 2b, the semiconductor substrate 100 is etched to a predetermined depth using the etch barrier layer 120 as a mask, thus forming a shallow trench 13.

Next, as shown in FIG. 2c, a liner oxide layer 140 is formed on the surface of the trench 130, the liner oxide layer 140 may be an insulation material, such as silicon oxide. As shown in FIG. 2d, the trench 130 is filled with the insulation material, such as silicon oxide, which also covers the entirety of the etch barrier layer 120 and the sidewall of the liner oxide layer 140 so as to form an isolation oxide layer 150. As shown in FIG. 2e, a planarization process, e.g. a chemical-mechanical polishing process is performed on the isolation oxide layer 150 so as to remove the isolation oxide layer 150 on the etch barrier layer 120. Finally, as shown in FIG. 2f, the etch barrier layer 120 and the pad oxide layer 110 are removed. A wet etching process is typically used to remove the pad oxide layer 110. Since the wet etching process is isotropic, it is likely to remove a portion of the insulation material on the sidewall of the trench 130. As a result, as shown in FIG. 2f, a shallow trench isolation structure in which a recess 160 is formed on the sidewall of the trench 130 is formed.

Charges may accumulate in the recess 160, thereby creating sub-threshold leakage currents in the devices of the integrated circuit. This phenomenon is called kink effect, which results in the reduction of the device reliability and yield. Moreover, since residue is remained in the recess 160 during the word line etching process, the devices are prevented from operating stably. Furthermore, the Fringing Electric Field generated in the recess 160 results in a characteristic hump in the plot of the transistor, thus increasing the sub-threshold currents and creating Inverse Narrow Width Effects. As a result, the device characteristic is degraded.

In Chinese patent application No. CN03825402, there is provided a method for fabricating a shallow trench isolation structure, by which the problem relating to the recess on the sidewall of the trench is resolved. As shown in FIG. 3a, a pad oxide layer 62, a first silicon nitride layer 64, a second silicon oxide layer 66 and a second silicon nitride layer 68 are sequentially formed on a silicon substrate. Subsequently, a trench 70 is formed by anisotropic etching. As shown in FIG. 3b, the trench 70 is exposed to an oxidation etching agent in an isotropic manner, and the pad oxide layer 62 and the second silicon oxide layer 66 are undercut, respectively. Subsequently, as shown in FIG. 3c, a liner oxide layer 76 is formed on the surface of the exposed silicon substrate 60. Subsequently, as shown in FIG. 3d, an oxide material is deposited in the trench 70 and on the second silicon nitride layer 68, and then the oxide layer on the second silicon nitride layer 68 is removed by a chemical mechanical polishing (CMP) process. Thereafter, as shown in FIG. 3e, the second silicon nitride layer 68 and the second silicon oxide layer 66 are removed sequentially so as to expose the first silicon nitride layer 64. Finally, the first silicon nitride layer 64 and the pad oxide layer 62 are removed, thus forming the structure as shown in FIG. 3e. However, the above-described method for forming the isolation trench is complicated, and the over-etching of the sidewall of the trench 70 during the removing of the pad oxide 62 still cannot be avoided.

### SUMMARY OF THE INVENTION

The present invention is to resolve the problem relating to conventional shallow trench isolation structures in which recesses may be formed on the sidewalls of the trenches.

The present invention provides a method for forming a shallow trench isolation structure, comprising the steps of:

Sequentially forming a pad oxide layer and an etch barrier layer on a semiconductor substrate, and sequentially etching the etch barrier layer, the pad oxide layer, and the substrate to form a trench;

Forming a liner oxide layer on the inner surface of the trench;

Forming a isolation oxide layer which fills up the trench and covers the sidewall of the pad oxide layer and the etch barrier layer;

Planarizing the isolation oxide layer until the etch barrier layer has been exposed;

Sequentially removing the etch barrier layer and the pad oxide layer on the substrate;

Forming a spin-on-glass layer on the substrate and the isolation oxide layer such that the recess on the sidewall of the trench is filled with the spin-on-glass;

Removing the spin-on-glass layer until both of the substrate and the isolation oxide layer have been exposed;

Wherein the spin-on-glass layer is made of silicon oxide;

Wherein the spin-on-glass layer needs to be annealed after it has been formed on the substrate and on the isolation oxide layer.

Wherein the thickness of the spin-on-glass layer after being annealed is in the range of 300 Å to 1000 Å, preferably, in the range of 300 Å to 500 Å.

Wherein the process of removing the spin-on-glass layer comprises the steps of:

Removing a portion of the spin-on-glass layer by a dry etching process such that the thickness of the remaining spin-on-glass layer is in the range of 100 Å to 200 Å;

Performing a wet etching process on the remaining spin-on-glass layer until both of the substrate and the isolation oxide layer have been exposed;

Wherein the dry etching process is a reactive ion etching (RIE) process.

Wherein the wet etching process is performed on the spin-on-glass layer using a hydrofluoric acid solution to remove the remaining spin-on-glass layer until both of the substrate and the isolation oxide layer have been exposed;

Wherein the substrate is made of silicon or silicon-on-insulator.

Wherein the pad oxide layer is made of silicon oxide or silicon oxynitride, the etch barrier layer is made of silicon nitride.

Wherein the isolation oxide layer is made of silicon oxide.

Wherein the etch barrier layer and the pad oxide layer are removed by a wet etching process.

According to the present invention, there is also provided a method for filling recesses, comprising the steps of: providing a semiconductor substrate containing recesses, forming a spin-on-glass layer on the substrate such that the recesses on the substrate is filled with the spin-on-glass; and performing the process of removing the spin-on-glass layer until the substrate has been exposed.

The advantages of the present invention compared to the prior art is in that:

1. After a trench isolation structure in which a recess is formed on the sidewall of a trench by a conventional process has been formed, a spin-on-glass layer is formed on the substrate and on a isolation filling layer by a spin-on-glass process. After the recess has been filled with the spin-on-glass, the spin-on-glass layer still has a relatively planar surface. Therefore, the trench isolation structure formed by the dry etch process and the wet etch process still has a planar surface. Also, the disadvantage that the recess is formed on the sidewall of the trench can thus be overcome.

2. The thickness of the spin-on-glass layer formed by the spin-on-glass process is in the range of 300 Å to 1000 Å, preferably, in the range of 300 Å to 500 Å. This not only ensures that the recess on the sidewall of the trench is filled up with the spin-on-glass, but also ensures that each of the substrate and the isolation trench structure still has a planar surface after the spin-on-glass layer has been removed by an etching process.

3. The process of removing the spin-on-glass layer comprises the two steps of: first, removing a portion of the spin-on-glass layer by the dry etching process such that the thickness of the remaining spin-on-glass layer is in the range of 100 Å to 200 Å; second, removing the remaining spin-on-glass layer by the wet etching process, thus ensuring that the surface of the monocrystalline silicon in the active region is not damaged during the process of removing the spin-on-glass layer.

### BRIEF DESCRIPTION OF THE DRAWINGS

FIG. 1 is a schematic diagram illustrating a “bird's beak” which is grown at the edge of a silicon nitride layer;

FIG. 2a to 2f are cross-sectional views illustrating a STI structure formed by one conventional STI process;

FIG. 3a to 3e are cross-sectional views illustrating a STI structure formed by another conventional STI process;

FIG. 4a to 4i are cross-sectional views illustrating a STI structure formed by a STI process according to the present invention.

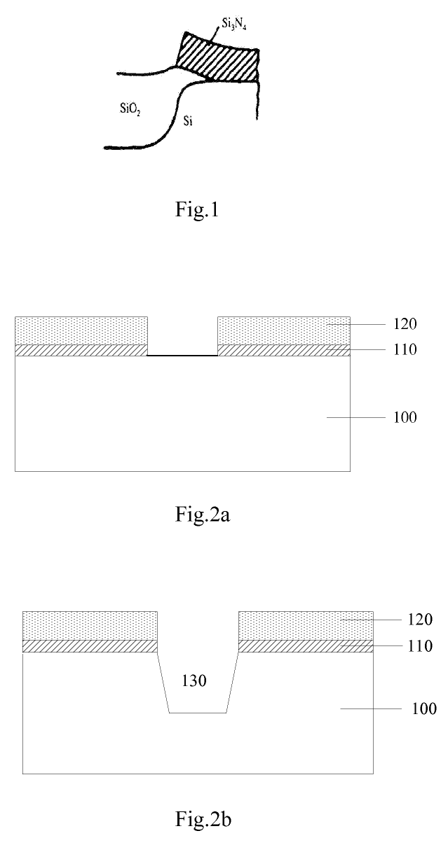

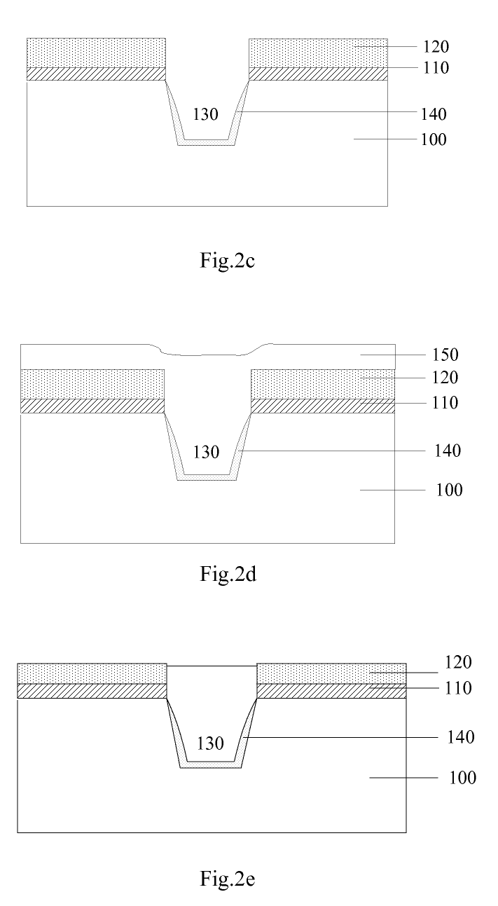

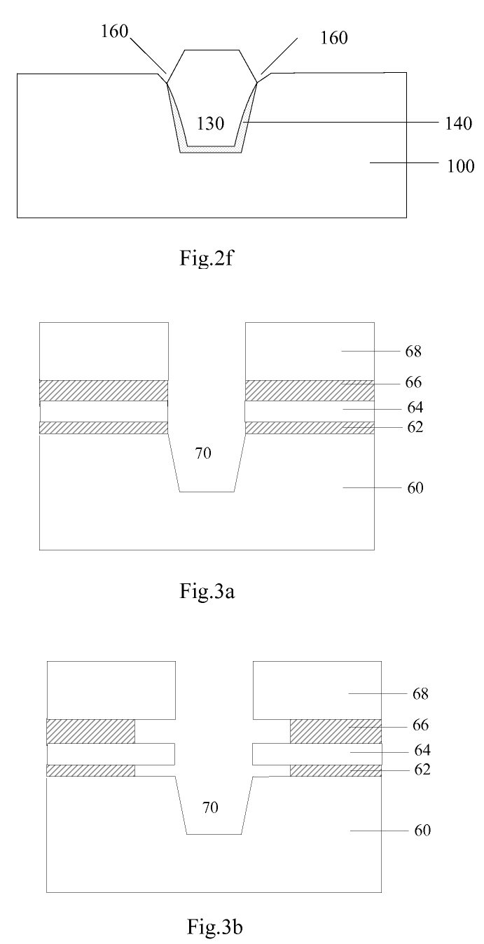

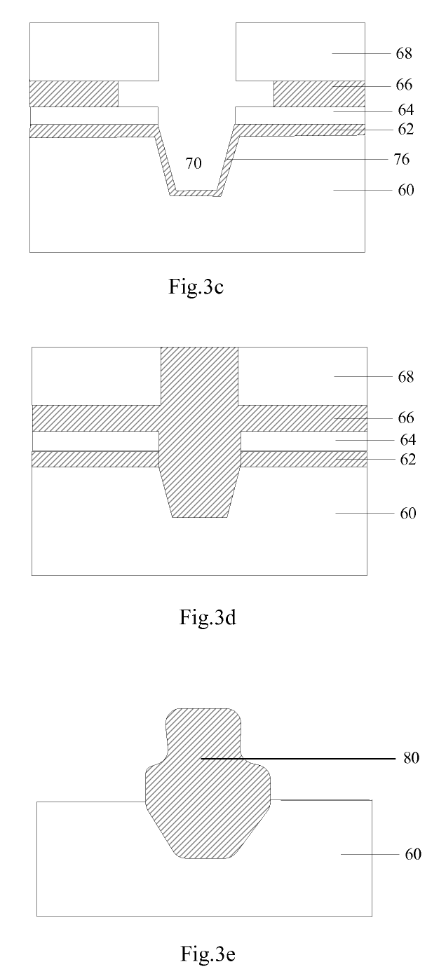

### DETAILED DESCRIPTION OF THE EMBODIMENTS

According to a particular embodiment of the present invention, there is provided a method for forming a trench isolation structure, comprising the steps of:

Sequentially forming a pad oxide layer and an etch barrier layer on a semiconductor substrate, and sequentially defining the etch barrier layer, the pad oxide layer, and the substrate to form a trench;

Forming a liner oxide layer on the inner surface of the trench;

Forming a isolation oxide layer which fills up the trench and covers the sidewall of the pad oxide layer and the etch barrier layer;

Performing a planarization process on the isolation oxide layer until the etch barrier layer has been exposed;

Sequentially removing the etch barrier layer and the pad oxide layer on the substrate; after both of the etch barrier layer and the pad oxide layer have been removed, a recess may be formed on the sidewall of the trench; for filling the recess on the sidewall of the trench, the method further comprises the following steps of:

Forming a spin-on-glass layer on the substrate and the isolation oxide layer such that the recess on the sidewall of the trench is filled with the spin-on-glass, and performing an annealing process on the spin-on-glass layer;

Thereafter, performing the process of removing the spin-on-glass layer until both of the substrate and the isolation oxide layer have been exposed; the process of removing the spin-on-glass layer comprises the two steps of: first, removing a portion of the spin-on-glass layer by a dry etching process such that the thickness of the remaining spin-on-glass layer is in the range of 100 Å to 200 Å; second, performing a wet etching process to remove the remaining spin-on-glass layer until both of the substrate and the isolation oxide layer have been exposed.

The particular embodiment of the present invention will now be described in detail with reference to the accompanying drawings.

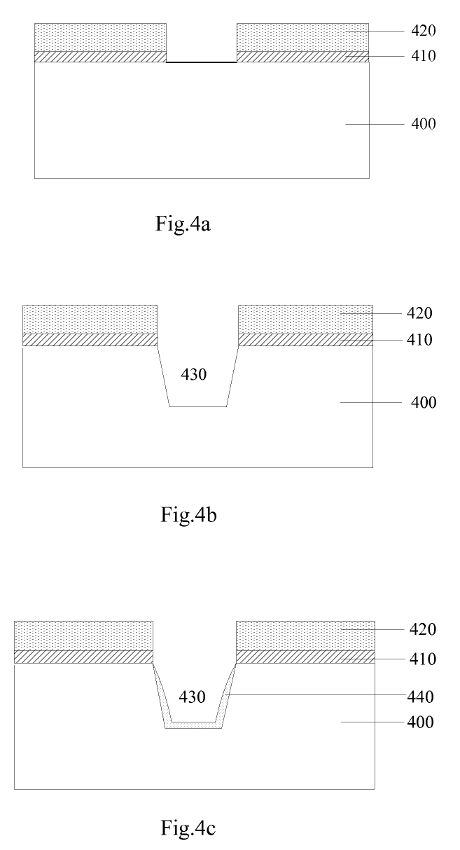

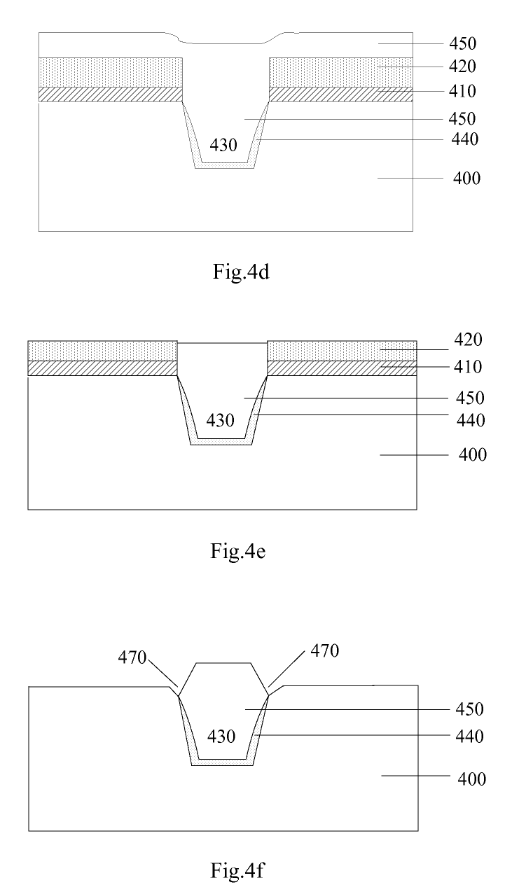

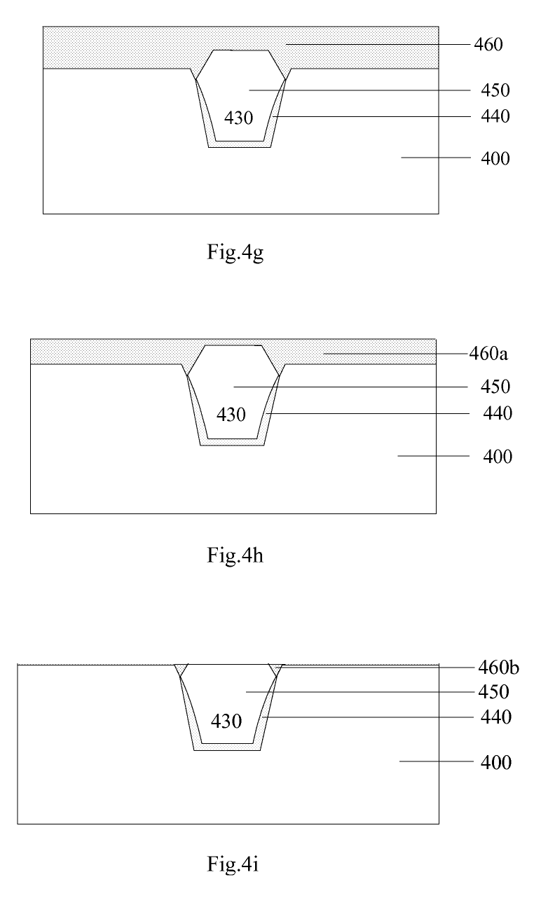

First, as shown in FIG. 4a, a pad oxide layer 410 and an etch barrier layer 420 are formed on a substrate 400. Thereafter, A photoresist layer is sprayed on the etch barrier layer 420, and the opening of the photoresist layer is formed by using an exposure process and a developing process, etc. The region on the substrate 400 corresponding to the position of the opening of the photoresist layer is an isolation region, and the rest region on the substrate is an active region. Using the photoresist layer as a mask, the etch barrier layer 420 and the pad oxide layer 410 are etched by an anisotropic etching process until the region on the substrate 400 where an isolation trench will be formed has been exposed. Finally, the photoresist layer on the etch barrier layer 420 is removed.

The substrate 400 is made of silicon or silicon-on-insulator. The pad oxide layer 410 may be made of silicon oxide, etc., and is typically formed by a thermal oxidation process. The pad oxide layer 410 can also be made of silicon oxynitride, and is typically formed by a low-pressure chemical vapor deposition process or a plasma enhanced chemical vapor deposition process. The etch barrier layer 420 is made of silicon nitride, for example, and is typically deposited on the pad oxide layer 410 by a chemical vapor deposition process.

As shown in FIG. 4b, the substrate 400 is etched to a predetermined depth using the etch barrier layer 420 as a mask, thus forming a trench 430. The substrate 400 may be etched by an anisotropic etching process, such as a reactive ion etching (RIR) process. Typically, the depth of the trench 430 is in the range of 0.1 μm to 1.5 μm.

As shown in FIG. 4c, a liner oxide layer 440 is formed on the inner surface of the trench 430. The liner oxide layer 440 may be made of silicon oxide, etc., and may be formed by a thermal oxidation process.

As shown in FIG. 4d, the trench 430 is filled with an insulation material, thus forming an isolation oxide layer 450. The isolation oxide layer 450 may be silicon oxide, etc. The trench 430 is filled up with the insulation material, which also covers the entirety of the pad oxide layer 410 and etch barrier layer 420, as shown in FIG. 4d. The isolation oxide layer 450 may be deposited in the trench 430 and on the etch barrier layer 420 by a chemical vapor deposition process. Preferably, this chemical vapor deposition process is a high-density plasma chemical vapor deposition (HDPCVD) process by which a silicon oxide insulation layer is deposited in the trench 430 and on the surface of the etch barrier layer 420 using O₂ and silane (SiH₄) as reactive gases.

Thereafter, as shown in FIG. 4e, the isolation oxide layer 450 is planarized, e.g., by a chemical mechanical polishing process until the etch barrier layer 420 has been exposed. Alternatively, the isolation oxide layer 450 is planarized by the chemical mechanical polishing process until the isolation oxide layer 450 has a relatively planar surface, the isolation oxide layer 450 is subsequently etched by an etching process until the etch barrier layer 420 has been exposed.

Finally, as shown in FIG. 4f, the etch barrier layer 420 and the pad oxide layer 410 are removed sequentially. The etch barrier layer 420 is removed e.g., by a wet etching process using a hot five-valent phosphoric acid solution. The pad oxide layer 410 is typically removed by a wet etching process, e.g., using a hydrofluoric acid solution. Since the wet etching process is isotropic, a portion of the insulation material on the sidewall of the trench 430 in contact with the semiconductor substrate may be etched when the pad oxide layer 410 is being removed by a hydrofluoric acid solution. As a result, as shown in FIG. 4f, a shallow trench isolation structure in which a recess 470 is formed on the sidewall of the trench 430 is formed.

As shown in FIG. 4g, a spin-on-glass layer 460 is formed on the substrate 400 and on the isolation oxide layer 450. The spin-on-glass layer 460 is preferably made of silicon oxide. The spin-on-glass layer 460 is formed by uniformly spreading a silicide-containing solution over the wafer by rotating the wafer, and then curing the silicide into non-crystalline silicon oxide by separating it from the solvent by heating.

In a particular embodiment of the present invention, a wafer with a structure as shown in FIG. 4f are rotated, and the methanol solution with a concentration of 15% to 25% silicon oxide is uniformly spread over the wafer. With the high speed rotation of the wafer, a silicon oxide film layer with a uniform thickness containing the solvent is formed on the surface of the wafer. Thereafter, in order to densify the spin-on-glass layer 460, an annealing process is performed at the temperature in the range of 850° C. to 1050° C. During the annealing process, methanol is vaporized, and a solid-state silicon oxide film layer with a uniform thickness is formed on the surface of the wafer. The thickness of the spin-on-glass layer would be reduced during the annealing process. According to the present invention, it is required that the thickness of the spin-on-glass layer after being annealed is in the range of 300 Å to 1000 Å. This not only ensures that the recess on the sidewall of the trench is filled up with the spin-on-glass, but also ensures that each of the substrate and the isolation oxide layer still has a relatively planar surface after the spin-on-glass layer has been removed by an etching process.

According to the present invention, the spin-on-glass layer 460 is formed by spinning coating using a liquid-state silicide solution, thus ensuring that each of the substrate 400 and the spin-on-glass layer 460 formed on the surface of the isolation oxide layer 450 still has a relatively planar surface after the recess on the sidewall of the trench 430 is filled up with the spin-on-glass.

According to the present invention, the thickness of the spin-on-glass layer 460 is in the range of 300 Å to 1000 Å, preferably, in the range of 300 Å to 500 Å. In some embodiments of the present invention, the thickness of the spin-on-glass layers are 400 Å, 600 Å, 700 Å, 800 Å, 900 Å, etc., respectively.

As shown in FIG. 4h, after the annealing process has been completed, the process of removing the spin-on-glass layer 460 is performed until both of the substrate 400 and the isolation oxide layer 450 have been exposed. According to the present invention, the process of removing the spin-on-glass layer 460 comprises the two steps of: first, removing a portion of the spin-on-glass layer 460 by a dry etching process such that the structure as shown in FIG. 4h is formed, the thickness of the remaining spin-on-glass layer 460a is in the range of 100 Å to 200 Å, thus ensuring that the surface of the substrate 400 will not be damaged during the dry etching process; second, removing the portion of the remaining spin-on-glass layer 460a that is higher than the substrate 400 by a wet etching process such that the structure as shown in FIG. 4i is formed.

The dry etching process of removing a portion of the spin-on-glass layer 460 may be a O₂ plasma etching process, for example. After the dry etching process has been completed, as shown in FIG. 4h, the thickness of the remaining spin-on-glass layer 460a is in the range of 100 Å to 200 Å, in some particular embodiments of the present invention, after the dry etching process has been completed, the thickness of the remaining spin-on-glass layers are 120 Å, 140 Å, 150 Å, 180 Å, etc., respectively. Since the spin-on-glass layer 460 has a relatively planar surface before the dry etching process is performed, the remaining spin-on-glass layer 460a still has a planar surface after the dry etching process has been completed.

The process of removing the remaining spin-on-glass layer 460a may be a wet etching process which is performed on silicon oxide using a hydrofluoric acid solution, for example. After the wet etching process has been completed, as shown in FIG. 4i, the structure in which only the recess on the sidewall of the trench 430 is filled with the spin-on-glass layer 460 is formed.

After a trench isolation structure in which a recess is formed on the sidewall of a trench by a conventional process has been formed, a spin-on-glass layer is formed on the substrate and on an isolation filling layer by a spin-on-glass process. After the recess has been filled with the spin-on-glass, the spin-on-glass layer still has a relatively planar surface. Therefore, the trench isolation structure formed by the dry etch process and the wet etch process still has a planar surface. Also, the disadvantage that the recess is formed on the sidewall of the trench can thus be overcome.

The above-described method for filling recesses according to the present invention is applicable for not only the shallow trench isolation structure, but also other semiconductor structures with recesses on surfaces. That method comprises the steps of: providing a semiconductor substrate containing recesses, forming a spin-on-glass layer on the substrate such that the recesses on the substrate is filled with the spin-on-glass; and removing the spin-on-glass layer until the substrate has been exposed.

The detailed method for filling recesses according to the present invention refers to the method for filling recesses on sidewalls of trenches in the shallow trench isolation process.

While the present invention has been disclosed with respect to certain preferred embodiments, the present invention is not limited thereto. Various changes and modifications may be made by those skilled in the art without departing from the spirit and scope of the invention. Thus the protection scope of the present invention should be as defined by the claims.

1. A method for forming a shallow trench isolation structure, comprising the steps of:
sequentially forming a pad oxide layer and an etch barrier layer on a semiconductor substrate, and sequentially etching the etch barrier layer, the pad oxide layer, and the semiconductor substrate to form a trench;
forming a liner oxide layer on the inner surface of the trench;
forming an isolation oxide layer which fills up the trench and covers the sidewall of the pad oxide layer and the etch barrier layer;
planarizing the isolation oxide layer until the etch barrier layer has been exposed;
sequentially removing the etch barrier layer and the pad oxide layer on the semiconductor substrate;
forming a spin-on-glass layer on the semiconductor substrate and the isolation oxide layer such that the recess on the sidewall of the trench is filled with the spin-on-glass; and
removing the spin-on-glass layer until both of the substrate and the isolation oxide layer have been exposed.

2. The method according to claim 1, wherein the spin-on-glass layer is made of silicon oxide.

3. The method according to claim 1, further including the annealing the spin-on-glass layer after it has been formed on the substrate and on the isolation oxide layer.

4. The method according to claim 3, wherein the thickness of the spin-on-glass layer after being annealed is in the range of 300 Å to 1000 Å.

5. The method according to claim 4, wherein the thickness of the spin-on-glass layer after being annealed is in the range of 300 Å to 500 Å.

6. The method according to claim 1, wherein the step of removing the spin-on-glass layer comprises the steps of:
removing a portion of the spin-on-glass layer by a dry etching process until the thickness of the remaining spin-on-glass layer is in the range of 100 Å to 200 Å;
performing a wet etching process on the remaining spin-on-glass layer until both of the substrate and the isolation oxide layer have been exposed;

7. The method according to claim 6, wherein the dry etching process is a reactive ion etching process.

8. The method according to claim 6, wherein the wet etching process is performed on the spin-on-glass layer using a hydrofluoric acid solution.

9. The method according to claim 1, wherein the substrate is silicon or silicon-on-insulator.

10. The method according to claim 1, wherein the pad oxide layer is made of silicon oxide or silicon oxynitride, and the etch barrier layer is made of silicon nitride.

11. The method according to claim 1, wherein the isolation oxide layer is made of silicon oxide.

12. The method according to claim 1, wherein the etch barrier layer and the pad oxide layer are removed by a wet etching process.

13. A method for filling recesses, comprising the steps of:
providing a semiconductor substrate containing recesses, forming a spin-on-glass layer on the substrate such that the recesses on the substrate is filled with the spin-on-glass; and
removing the spin-on-glass layer until the substrate has been exposed.

14. The method according to claim 2, wherein the step of removing the spin-on-glass layer comprises the steps of:
removing a portion of the spin-on-glass layer by a dry etching process until the thickness of the remaining spin-on-glass layer is in the range of 100 Å to 200 Å;
performing a wet etching process on the remaining spin-on-glass layer until both of the substrate and the isolation oxide layer have been exposed;

15. The method according to claim 14, wherein the dry etching process is a reactive ion etching process.

16. The method according to claim 14, wherein the wet etching process is performed on the spin-on-glass layer using a hydrofluoric acid solution.

17. The method according to claim 3, wherein the step of removing the spin-on-glass layer comprises the steps of:
removing a portion of the spin-on-glass layer by a dry etching process until the thickness of the remaining spin-on-glass layer is in the range of 100 Å to 200 Å;
performing a wet etching process on the remaining spin-on-glass layer until both of the substrate and the isolation oxide layer have been exposed;

18. The method according to claim 17, wherein the dry etching process is a reactive ion etching process.

19. The method according to claim 17, wherein the wet etching process is performed on the spin-on-glass layer using a hydrofluoric acid solution.

20. The method according to claim 4, wherein the step of removing the spin-on-glass layer comprises the steps of:
removing a portion of the spin-on-glass layer by a dry etching process until the thickness of the remaining spin-on-glass layer is in the range of 100 Å to 200 Å;
performing a wet etching process on the remaining spin-on-glass layer until both of the substrate and the isolation oxide layer have been exposed;
